(19) United States
(12) Patent Application Publication
(10) Pub. No.: US 2023/0119980 A1
(43) Pub. Date: Apr. 20, 2023

(54) A METHOD OF MANUFACTURING SEGREGATED LAYERS ABOVE A SUBSTRATE, AND A METHOD FOR MANUFACTURING A DEVICE

(71) Applicant: Merck Patent GmbH, Darmstadt (DE)

(72) Inventors: Daniel HUDSON, Branchburg, NJ (US); Changsheng WANG, Branchburg, NJ (US); Kornel OCYTKO, Branchburg, NJ (US); Graham MORSE, Branchburg, NJ (US); Ben JEFFERY, Branchburg, NJ (US); Ralph R. DAMMEL, Branchburg, NJ (US); Takanori KUDO, Branchburg, NJ (US)

(21) Appl. No.: 17/910,000

(22) PCT Filed: Mar. 8, 2021
(86) PCT No.: PCT/EP2021/055699

§ 371 Date: Sep. 8, 2022

Related U.S. Application Data
(60) Provisional application No. 62/988,043, filed on Mar. 11, 2020.

(51) Int. Cl. G03F 1/76; G03F 1/46; G03F 1/60; B05D 1/00; B05D 3/02; B05D 7/00

(52) U.S. Cl. CPC G03F 1/76; G03F 1/46; G03F 1/60; B05D 1/005; B05D 3/0254; B05D 7/532; B05D 2401/10; B05D 2507/005; B05D 2506/00; B05D 2518/12

(57) ABSTRACT

The present invention pertains to a method of manufacturing segregated layers above a substrate. The invention also pertains to methods of manufacturing a photoresist layer, photoresist patterns, a processed substrate and a device.

### FIELD OF INVENTION

The present invention relates to a method of manufacturing segregated layers above a substrate. And present invention also relates to methods of manufacturing a photoresist layer, photoresist patterns, a processed substrate and a device.

### BACKGROUND

Because there is a tendency to require more miniaturized apparatuses with higher performance, more fine patterning is required in devices (for example, semiconductor device, FPD device). Lithography technology using a photoresist (can be referred to “resist” herein after) is generally employed for fine processing. To support resist patterning in high fine level, other functional layers, for example, top antireflective coating (TARC), bottom antireflective coating (BARC), Spin-on carbon (SOC) coating and so on are developed. However, such multi-layer structure may complicate fabrication process and may render it time consuming and costly.

Under these circumstances, to limit crystalline defects introduced in a semiconductor device during ion implantation, a specific process concept is proposed with using tri-layer photoresist (Patent Literature 1). However, some proof of concept is not delivered by any experiment in Patent Literature 1.

In order to reduce processing steps in semiconductor fabrication, a self-segregating polymeric composition is proposed to be segregated to photoresist layer on BARC layer (Patent Literature 2). However, only patterning ability is confirmed, and self-segregation was not confirmed in Patent Literature 2.

### CITATION LIST

### Patent Literature

[Patent Literature 1] US2014/0061738A

[Patent Literature 2] US2010/0009132A

[Patent Literature 3] U.S. Pat. No. 9,274,426B2

### SUMMARY OF INVENTION

### Technical Problem

The inventors have found that there are still one or more considerable problems for which improvement are desired, as listed below; difficult to achieve segregated layers with good properties by one application process; the separate applying processes for plural layers are time consuming and costly; difficult to obtain a silicon rich upper surface in segregated layers; reflective indexes of the upper surface in segregated layers are insufficient; etch rate of segregated layers are insufficient, and/or difficult to tune good adaption for the process; uniformities of segregated layers are insufficient; voids and/or defects in segregated layers occur in large numbers; thermal stabilities of segregated layers are insufficient; the composition used in the method are insufficient for gap filing; solvent resistance of the upper surface in the segregated layers are insufficient and difficult to avoid intermixing with upper photoresist composition/layer; difficult to apply photoresist composition/layer above the segregated layers with good wettability.

Then, the inventors found that the inventions described below solves at least one of these problems.

### Solution to Problem

The present invention provides a method of manufacturing segregated layers above a substrate, comprising: (1) applying a composition above said substrate, wherein said composition comprises solvent (A), siloxane polymer (B) and high-carbon material (C); and (2) heating said substrate to form segregated layers of antireflective coating made from siloxane polymer (B) and spin-on-carbon coating made from high-carbon material (C), where placed said antireflective coating, spin-on-carbon coating and substrate in this order.

The present invention also provides a method of manufacturing a photoresist layer, comprising: (3) applying a photoresist composition above the segregated layers; and (4) heating said substrate to form photoresist layer.

The present invention also provides a method of manufacturing photoresist patterns, comprising: (5) exposing the photoresist layer; and (6) developing said exposed layer to form photoresist pattern.

The present invention also provides a method of manufacturing a processed substrate, comprising: (7) etching through the resist pattern as a mask; and (8) processing the substrate.

Also, the present invention provides a method of manufacturing a device.

One another aspect of the present invention provides a composition self-segregating to antireflective coating and spin-on-carbon coating, comprising solvent (A), siloxane polymer (B) and high-carbon material (C).

### Effects of the Invention

The method can make segregated layers by one application process. The method can reduce time and cost to apply spin-on-carbon coating and antireflective coating above substrate separately. The segregated layers can have a silicon rich upper surface. The upper surface of the segregated layer can exhibit a good reflective index. The segregated layers can exhibit good etch rate and etch resistance, and these can be tuned by high-carbon material. The method can form segregated layers with good uniformity. The segregated layers made from the method can decrease voids and/or defects. The segregated layers can exhibit a good thermal stability. The composition used in the method can exhibit good gap filling property. The segregated layers can exhibit good solvent resistance and can avoid intermixing with upper photoresist composition/layer. The upper surface of the segregated layers can exhibit good wettability of a photoresist composition/layer.

### BRIEF DESCRIPTION OF DRAWINGS

FIG. 1 is a silicon content evaluation data. In FIG. 1 “Work c.” means “working composition”.

### DESCRIPTION OF EMBODIMENTS

The above summary and the following details are provided for illustration of the present invention and are not intended to limit the claimed invention.

### DETAILED DESCRIPTION

Throughout this specification, below defined symbols, units, abbreviations and terms have the meanings given in below definitions, descriptions and examples, unless explicitly limited or stated.

The use of the singular includes the plural, and the words “a”, “an” and “the” mean “at least one”. Furthermore, the use of the term “including”, as well as other forms such as “includes” and “included”, is not limiting. Also, terms such as “element” or “component” encompass both elements or components comprising one unit and elements or components that comprise more than one unit.

The term “and/or” refers to any combination of the any foregoing elements including using a single element.

When a numerical range is specified herein using “−”, “to” or “˜”, the numerical range includes both of the numbers indicated before and after “−”, “to” or “˜” and the unit is the same for the two numbers. For example, “5-25 mol %” means “5 mol % or more and 25 mol % or less”.

The terms such as “C_{x-y}”, “Cₓ-C_{y}”, and “Cₓ” as used herein represent the number of carbon atoms in a molecule or substituent. For example, “C₁₋₆ alkyl” refers to an alkyl chain having 1-6 carbon atoms (such as methyl, ethyl, propyl, butyl, pentyl, hexyl and so on).

When a polymer as described herein has plural types of repeating units, these repeating units are copolymerized. The copolymerization may be any one selected from alternating copolymerization, random copolymerization, block copolymerization, graft copolymerization, and any combination of any of these. When a polymer or resin is represented by a chemical structure, n, m and so on put down with brackets means repeating numbers.

The unit of temperatures as indicated herein is degree Celsius. For example, “20 degrees” means “20 degrees Celsius”.

When additive (e.g., cross linker, surfactant) is described, the additive means the compound itself plays its function. For example, when base generator is described, it means a compound generating base. As a practical embodiment, such compound can be dissolved or dispersed in a solvent, and then comprised by a composition. As one embodiment of the invention, such solvent is preferably comprised as solvent (A) in the segregating composition.

Composition

Herein later, a composition is described which is applied above a substrate in the manufacturing method of this invention. As this composition segregates to antireflective coating and spin-on-carbon coating, this composition can be said segregating composition. In one embodiment of the invention said composition essentially consists of a segregating composition.

The composition comprises solvent (A), siloxane polymer (B) and high-carbon material (C).

In another aspect of the invention the composition is self-segregating to antireflective coating and spin-on-carbon coating and comprises an antireflective coating and a spin-on-carbon coating.

Another aspect of the invention is the use of a composition for self-segregating to antireflective coating and spin-on-carbon coating, which comprises an antireflective coating and a spin-on-carbon coating.

Solvent (A)

Solvent (A) can comprise any type of solvent. In one embodiment of the invention said solvent (A) comprises an organic solvent. Preferably the organic solvent comprises hydrocarbon solvent, ether solvent, ester solvent, alcohol solvent, ketone solvent, or any mixture of any of these.

Examples of the (A) solvents include: aliphatic hydrocarbon solvents such as n-pentane, i-pentane, n-hexane, i-hexane, n-heptane, i-heptane, cyclohexane, and methylcyclohexane; aromatic hydrocarbon solvents such as benzene, toluene, xylene, ethylbenzene, trimethylbenzene, methylethylbenzene, n-propylbenzene, i-propylbenzene, diethylbenzene, and i-butylbenzene; monoalcohol solvents such as methanol, ethanol, n-propanol, i-propanol, n-butanol, i-butanol, sec-butanol, t-butanol, n-pentanol, i-pentanol, 2-methylbutanol, 2-ethylhexanol, n-nonyl alcohol, 2,6-dimethylheptanol-4, n-decanol, cyclohexanol, benzyl alcohol, phenylmethylcarbinol, diacetone alcohol, and cresol; polyol solvents such as ethylene glycol, propylene glycol, 1,3-butylene glycol, diethylene glycol, dipropylene glycol, triethylene glycol, tripropylene glycol, and glycerin; ketone solvents such as acetone, methyl ethyl ketone, methyl n-propyl ketone, methyl n-butyl ketone, diethyl ketone, trimethylnonanone, cyclohexanone, cyclopentanone, methylcyclohexanone, 2,4-pentanedione, acetonylacetone, acetophenone, and fenchone; ether solvents such as ethyl ether, i-propyl ether, n-butyl ether (DBE), n-hexyl ether, 2-ethylhexyl ether, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, propylene glycol monomethyl ether (PGME), propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyltetrahydrofuran; ester solvents such as diethyl carbonate, methyl acetate, ethyl acetate, γ-butyrolactone, γ-valerolactone, n-propyl acetate, i-propyl acetate, n-butyl acetate (nBA), i-butyl acetate, n-decyl acetate, n-butyl propionate, methyl lactate, ethyl lactate (EL), γ-butyrolactone, n-butyl lactate, n-amyl lactate, diethyl malonate, dimethyl phthalate, diethyl phthalate, propylene glycol 1-monomethyl ether 2-acetate (PGMEA), Di (propylene glycol) methyl ether acetate (Di(PGMEA)), propylene glycol monoethyl ether acetate, cyclohexyl hexanoate, and propylene glycol monopropyl ether acetate; nitrogen-containing solvents such as N-methylformamide; and sulfur-containing solvents such as dimethyl sulfide. Any mixture of any of these solvents can also be used.

In one embodiment of this invention said solvent (A) comprises at least one high boiling point solvent, which is preferably Di(PGMEA), cyclohexyl hexanoate, n-decyl acetate, and any mixture of any of these; more preferably Di(PGMEA), n-decyl acetate, and any mixture of any of these; further preferably mixture of Di(PGMEA) and n-decyl acetate. While wishing not to be bound by the theory, but it is thought by the inventors that by the presence of a high boiling point solvent, the drying time of the composition, after applied above substrate, can be extended enabling better segregation of components to separate layers. Solvent(s) in the solvent (A) other than high boiling solvent can be the base solvent.

In one embodiment of this aspect of the invention, such high boiling point solvent has a boiling point which is more than 50% higher (preferably 50-150% higher, more preferably 70-125% higher) than said base solvent. If there are a plural species of high boiling solvents or base solvents in solvent (A), the boiling point is obtained by each of mean value.

Said base solvent is preferably PGME, PGMEA, EL, nBA, DBE and any mixture of any of these; more preferably PGME, PGMEA and mixture of these; further preferably mixture of PGME and PGMEA.

The mass ratio of high boiling point solvent to base solvent is preferably 5-30%; more preferably 10-25%, further preferably 10-20%.

If the high boiling point solvent or base solvent is mixture of 2 plural species in each, mass ratio of 1^{st} solvent and 2^{nd} solvent is preferably 90:10-10:90; more preferably 80:20-20:80. If the high boiling point solvent or base solvent is mixture of 3 plural species in each, the mass ratio of 1^{st} solvent to sum of 3 species is preferably 30-90% (more preferably 50-80%, further preferably 60-70%); 2^{nd} solvent to sum of 3 species is preferably 10-50% (more preferably 20-40%); 3^{rd} solvent to sum of 3 species is preferably 5-40% (more preferably 5-20%, further preferably 5-15%).

The solvent (A) preferably comprise an organic solvent, and the amount of water in the solvent (A) is preferably 0.1 mass % or less and further preferably 0.01 mass % or less. Given the relationship with another layer or coating, it is preferable for the solvent (A) to be free of water.

In one embodiment of this invention the mass ratio of the solvent (A) based on the total mass of the segregating composition is 60-99 mass %; preferably 70-97 mass %; more preferably 80-95 mass %; further preferably 90-95 mass %.

Siloxane Polymer (B)

Siloxane polymer (B) can comprise at least one unit selected from the group consisting of unit B1, unit B2 and unit B3.

Unit B1 is represented by formula B1.

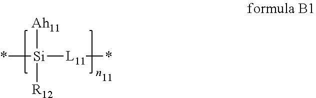

Ah₁₁ is C₁₋₅ aliphatic hydrocarbon. Ah₁₁ is preferably methyl, ethyl, n-propyl, isopropyl, t-butyl, vinyl (H₂C═CH—), or ethynyl (HO≡C—); more preferably methyl or t-butyl; further preferably methyl.

R₁₂ is -Ah₁₂, —O-Ah₁₂, —O—*, —Si(H)ₚ₁₂ (Ah₁₂)_{q12}, —O—Si(H)ₚ₁₂(Ah₁₂)_{q12}, or a single bond to other unit. R₁₂ is preferably -Ah₁₂, —O-Ah₁₂, —Si(H)ₚ₁₂(Ah₁₂)_{q12}, or —O—Si(H)ₚ₁₂(Ah₁₂)_{q12}; more preferably -Ah₁₂, or —O—Si(H)ₚ₁₂(Ah₁₂)_{q12}; further preferably -Ah₁₂. In one embodiment of the invention R₁₂ is —O—Si(H)ₚ₁₂(Ah₁₂)_{q12}.

“*” means single bond to other unit and/or polymer terminal. Said single bond may bind other unit via another single bond and/or aliphatic hydrocarbon in the polymer. The term “other unit” doesn't comprise one unit B1 which the single bond exists in. But in the case that Siloxane polymer (B) comprise plural unit B1s, the single bond can bond to other unit B1 (not unit B1 which the single bond exists in, not self-crosslinking in one unit B1). Same in herein later, otherwise specifically described.

“Single bond to other unit” means single bond boding to other unit. Same herein later, otherwise specifically described.

Ah₁₂ is C₁₋₅ aliphatic hydrocarbon. Ah₁₂ is preferably methyl, ethyl, n-propyl, isopropyl, t-butyl, vinyl, or ethynyl; more preferably methyl, t-butyl or vinyl; further preferably methyl or vinyl, further, more preferably methyl.

Below is one exemplified siloxane polymer (B) comprise 2 species of unit B1s. Middle 2 unit B1s provide R₁₂s of —O—* and a single bond to other unit which bonding each other. Each of Ah₁₁ of middle 2 unit B1s are methyl.

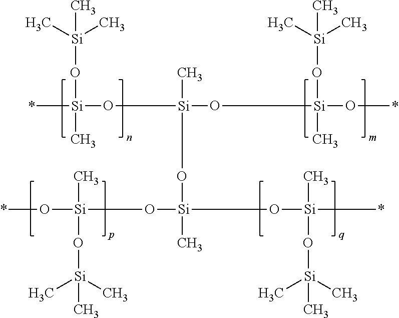

p12=0, 1, 2 or 3. p12 is preferably 0 or 1; more preferably 0. q12=0, 1, 2 or 3. q12 is preferably 2 or 3; more preferably 3. p12+q12=3.

L₁₁ is single bond or —O—; preferably —O—.

n₁₁ is repeating number of unit B.

Exemplified unit B1 are below without intent to limit the scope of the claim of the invention.

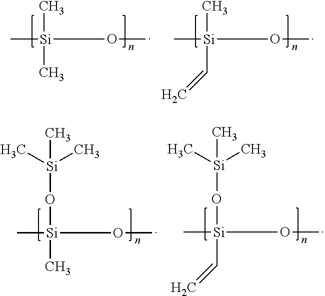

Unit B2 is represented by formula B2.

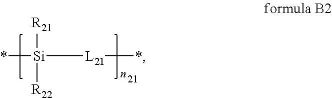

R₂₁ is -Ah₂₁, —O-Ah₂₁, —O—*, —Si(H)ₚ₂₁(Ah₂₁)_{q21}, —O—Si(H)ₚ₂₁(Ah₂₁)_{q21}, or a single bond to other unit. R₂₁ is preferably —O-Ah₂₁, —O—*, —Si(H)ₚ₂₁(Ah₂₁)_{q21}, —O—Si(H)ₚ₂₁(Ah₂₁)_{q21}, or a single bond to other unit; more preferably —O-Ah₂₁, —Si(H)ₚ₂₁(Ah₂₁)_{q}21, or —O—Si(H)ₚ₂₁(Ah₂₁)_{q21}; further preferably —O—Si(H)ₚ₂₁(Ah₂₁)_{q21}.

R₂₂ is -Ah₂₂, —O-Ah₂₂, —O—*, —Si(H)ₚ₂₂(Ah₂₂)_{q22}, —O—Si(H)ₚ₂₂(Ah₂₂)_{q22}, or a single bond to other unit. R₂₂ is preferably —O-Ah₂₂, —O—*, —Si(H)ₚ₂₂(Ah₂₂)_{q22}, —O—Si(H)ₚ₂₂(Ah₂₂)_{q22}, or a single bond to other unit; more preferably —O-Ah₂₂, —Si(H)ₚ₂₂(Ah₂₂)_{q22}, or —O—Si(H)ₚ₂₂(Ah₂₂)_{q22}; further preferably —O—Si(H)ₚ₂₂(Ah₂₂)_{q22}.

Ah₂₁ and Ah₂₂ are each independently C₁₋₅ aliphatic hydrocarbon. Each independently Ah₂₁ and Ah₂₂ is preferably methyl, ethyl, n-propyl, isopropyl, t-butyl, vinyl (H₂C═CH—), or ethynyl (HC≡C—); more preferably methyl or t-butyl; further preferably methyl.

p21, p22, q21 and q22 are each independently 0, 1, 2 or 3. Each independently p21 and p22 is preferably 0 or 1; more preferably 0. Each independently q21 and q22 is preferably 2 or 3; more preferably 3. p21+q21=p22+q22=3.

L₂₁ is single bond or —O—; preferably —O—.

n₂₁ is repeating number of unit B2.

Exemplified unit B2 are below without intent to limit the scope of the claim of the invention.

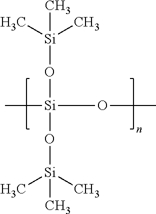

Unit B3 is represented by formula B3.

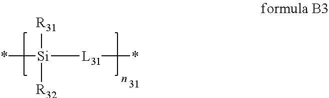

R₃₁ is -Ah₃₁, —O-Ah₃₁, —O—*, —Si(H)ₚ₃₁(Ah₃₁)_{q31}, —O—Si(H)ₚ₃₁(Ah₃₁)_{q31}, or a single bond to other unit. R₃₁ is preferably -Ah₃₁, —Si(H)ₚ₃₁(Ah₃₁)_{q31}, or —O—Si(H)ₚ₃₁(Ah₃₁)_{q31}; more preferably -Ah₃₁, or —O—Si(H)ₚ₃₁(Ah₃₁)_{q31}; further preferably -Ah₃₁. In one embodiment of the invention R₃₁ is —O—Si(H)ₚ₃₁(Ah₃₁)_{q31}.

Ah₃₁ is C₁₋₅ aliphatic hydrocarbon. Ah₃₁ is preferably methyl, ethyl, n-propyl, isopropyl, t-butyl, vinyl, or ethynyl; more preferably methyl, t-butyl or vinyl; further preferably methyl or vinyl, further, more preferably methyl. p31=0, 1, 2 or 3. p31 is preferably 0 or 1; more preferably 0. q31=0, 1, 2 or 3. q31 is preferably 2 or 3; more preferably 3. p31+q31=3.

R₃₂ is a group consisting of at least 2 group and/or linker selected from the group consisting of phenyl, phenylene, —O—, —(C═O)—, —COO—, —COOH, —NH—, C₁₋₅ aliphatic hydrocarbon group and C₁₋₅ aliphatic hydrocarbon linker. One linker of R₃₂ can bond to other linker to make hydrocarbon ring or heterocyclic group; preferably aromatic ring or heteroaromatic group; more preferably heteroaromatic group.

Below is one exemplified siloxane polymer (B) which comprise unit B3. R₃₂ is constituted by the combination of n-propylene (C₃ aliphatic hydrocarbon linker), —NH—, —(C═O)—, sec-butylene (C₄ aliphatic hydrocarbon linker), and —(C═O)—, in this order, of which the terminal —(C═O)— bonds to —NH— to make heteroaromatic group.

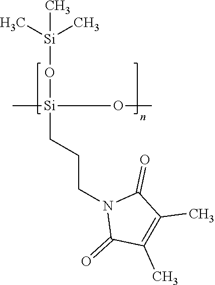

In one embodiment of the invention R₃₂ is a group consisting of preferably 2-7 (more preferably 2-6; further preferably 3-5) group and/or linker. In one embodiment of the invention R₃₂ is a group consisting of at least 2 group and/or linker selected from the group consisting of preferably phenyl, phenylene, —O—, —(C═O)—, —COO—, —COOH, —NH—, C₁₋₅ aliphatic hydrocarbon group and C₁₋₅ aliphatic hydrocarbon linker; more preferably phenylene, —O—, —(C═O)—, —COO—, —NH—, Cis aliphatic hydrocarbon group and Cis aliphatic hydrocarbon linker.

L₃₁ is single bond or —O—; preferably —O—.

n₃₁ is repeating number of unit B3.

Exemplified unit B3 are below without intent to limit the scope of the claim of the invention.

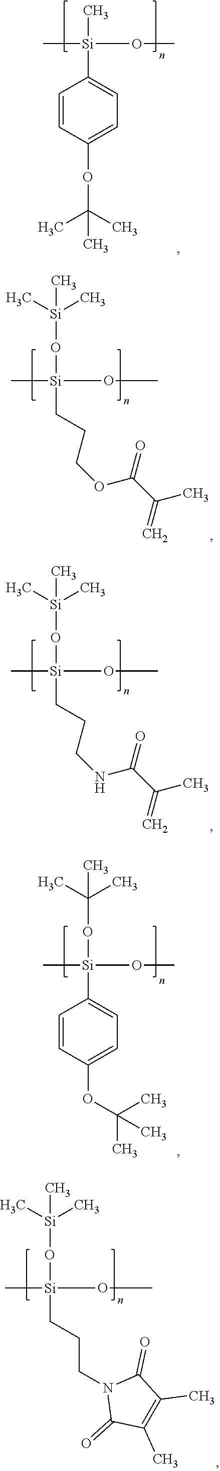

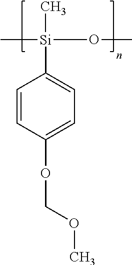

While not wishing to be bound by the theory, the inventors think that a protection group (e.g., t-butyl, methoxymethyl ether) works to maintain hydrophobicity polysiloxane layer until phase separation occurs.

Weight average molecular weight (Mw) of the siloxane polymer (B) is preferably 1,000-100,000; more preferably 2,000-50,000; further preferably 3,000-20,000; further, more preferably 3,000-10,000.

Mw and Mn (number average molecular weight) can be measured by known method. When sample is polymer, In one preferable embodiment the measurement method is the one used for working examples, as described herein later. And monodisperse polystyrene can be used as standard.

n₁₁, n₂₁, and n₃₁ are repeating number of unit B1, B2 and B3 in siloxane polymer (B). 0%≤n₁₁/(n₁₁+n₂₁+n₃₁)≤80%, 0%≤n₂₁/(n₁₁+n₂₁+n₃₁)≤80%, and 0%≤n₃₁/(n₁₁+n₂₁+n₃₁)≤80%.

n₁₁/(n₁₁+n₂₁+n₃₁) is preferably 5-75%; more preferably 10-70%; further preferably 20-70%; further, more preferably 30-70%.

n₂₁/(n₁₁+n₂₁+n₃₁) is preferably 0-75%; more preferably 0-70%; further preferably 0-60%; further, more preferably 0-40%.

n₃₁/(n₁₁+n₂₁+n₃₁) is preferably 5-75%; more preferably 10-60%; further preferably 10-50%; further, more preferably 10-40%.

As exemplified embodiment of siloxane polymer (B), ones used in working example herein later described can be raised.

In one embodiment of the invention is that said siloxane polymer (B), based on the total mass of the segregating composition, is 0.1-10 mass %; preferably 0.2-5 mass %; more preferably 0.5-5 mass %; further preferably 0.75-3 mass %; further, more preferably 0.90-2 mass %.

High-Carbon Material (C)

Spin-on-carbon coating manufactured by the invention is made from high-carbon material (C). Here, “made from” means coating structure is mainly constituted from high-carbon material (C) itself or compound/polymer formed from it. For example, one embodiment of the invention is that cross linker (E) can become a portion of the spin-on-carbon coating.

It is preferable that the spin-on-carbon coating of the invention exhibit high etch resistance. A preferable embodiment of the invention is that number of atoms contained in said spin-on-carbon coating satisfy below formula C1.

1.5≤{total number of atoms/(number of C−number of O)}≤3.5 formula C1

Number of C is the number of carbon atoms in the total number of atoms, and the number of O is the number of oxygen atoms in the total number of atoms. The total number of atoms in formula C1 includes the number of hydrogen atoms.

It can be said that atoms in solid components of the composition portion to be spin-on-carbon coating. It can be also said that the solid component of spin-on-carbon coating is a component that is formed into a spin-on-carbon coating. For example, atoms in solvent (A) is ignored to calculate the above atoms.

Formula C1 is preferably formula C1′; more preferably formula C1″.

1.5≤{total number of atoms/(number of C−number of O)}≤2.4 formula C1′

1.8≤{total number of atoms/(number of C−number of O)}≤2.4 formula C1″

High-carbon material (C) can comprise at least one selected from the group consisting of unit C2, molecule C3 and unit C4.

Unit C2 is represented by formula C2. Unit C2 can constitute polymer.

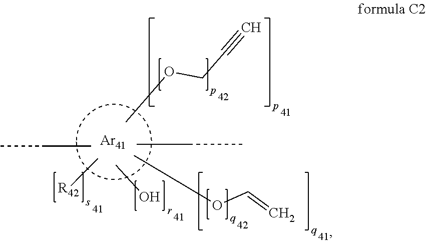

Ar₄₁ is C₆₋₆₀ hydrocarbon unsubstituted or substituted by R₄₁. Preferably Arai doesn't comprise fused aromatic ring. Arai is preferably 9,9-diphenyl fluorene, 9-phenyl-fluorene, phenyl, C₆₋₆₀ linear polyphenyl, and C₆₋₆₀ branched polyphenyl, each of which can be substituted by R₄₁.

R₄₁ is linear, branch or cyclic C₁₋₂₀ alkyl, amino or alkylamino; preferably linear, branch or cyclic C₁₋₁₀ alkyl, or alkylamino; further preferably linear C₁₋₃ alkyl, branched C₁₋₃ alkyl, cyclopentyl, cyclohexyl, or dimethylamino. When high-carbon material (C) comprise plural unit C2s, R₄₁ can intervene plural Ar₄₁s and combine them as a linker. One Ar41 can be substituted by a single or plurality of R₄₁; preferably substituted by a single of R₄₁.

In one unit C2, a group enclosed in brackets (e.g., a group enclosed in brackets which p₄₁ is described by side) can bond to R₄₁. In this case, the group and Arai are combined by R₄₁ working as a linker.

R₁₂ is I, Br or CN; preferably I or Br; more preferably I.

p₄₁ is number of 0-5. As one embodiment of this invention, high-carbon material (C) can comprise 2 species of unit C2s one by one. One example of the embodiment is both Ar₄₁ are phenyl and one p₄₁ is 1, and other p₄₁ is 2. In such case, p₄₁ is 1.5 as whole. Same herein later in this specification, otherwise specifically described.

p₄₁ is preferably 0, 1, 2 or 3; more preferably 0, 1 or 2; further preferably 0 or 1; further, more preferably 0. In another preferable embodiment of the invention p₄₁ is 1.

p₄₂ is number of 0-1; preferably 0 or 1; more preferably 1.

q41 is number of 0-5. q41 is preferably 0, 1, 2 or 3; more preferably 0, 1 or 2; further preferably 0 or 1; further, more preferably 0. In another preferable embodiment of the invention q41 is 1.

q₄₂ is number of 0-1; preferably 0 or 1; more preferably 1.

r₄₁ is number of 0-5; preferably 0, 1, 2, 3, 4 or 5; more preferably 0, 1, 2 or 3; further preferably 1 or 2; further, more preferably 1. In another preferable embodiment of the invention r₄₁ is 0.

s₄₁ is number of 0-5. r₄₁ is preferably 0, 1, 2 or 3; more preferably 0, 1 or 2; further preferably 0 or 1; further, more preferably 0. In another preferable embodiment of the invention r₄₁ is 1.

In a preferable embodiment of the invention p₄₁, q₄₁ and r₄₁ doesn't take 0 at the same time in one Unit C2.

When high-carbon material (C) is polymer, molecular weight of it use weight average molecular weight (Mw).

Preferably molecular weight of the high-carbon material (C) comprising unit C2 is 500-4,000; more preferably 500-3,000; further preferably 1,000-2,000.

Exemplified Unit C2s are described below, without intent to limit the scope of the invention.

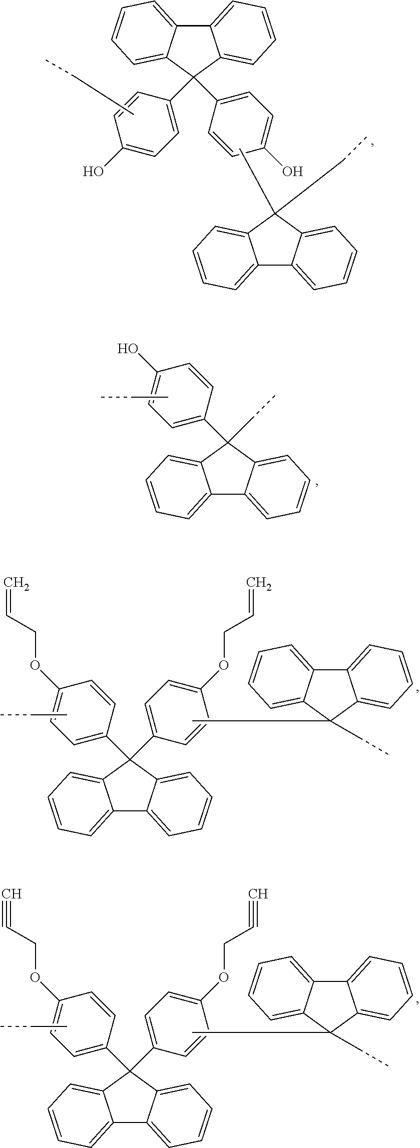

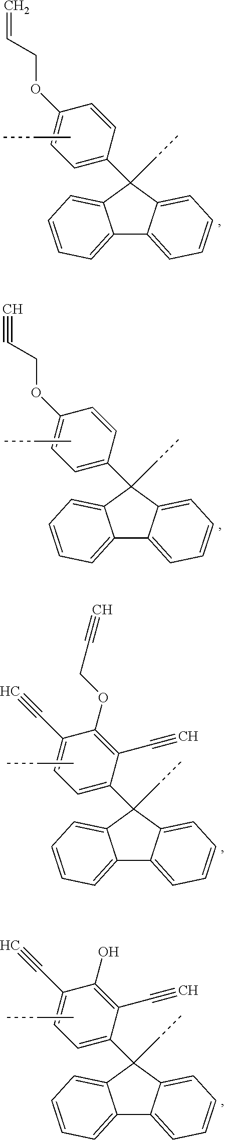

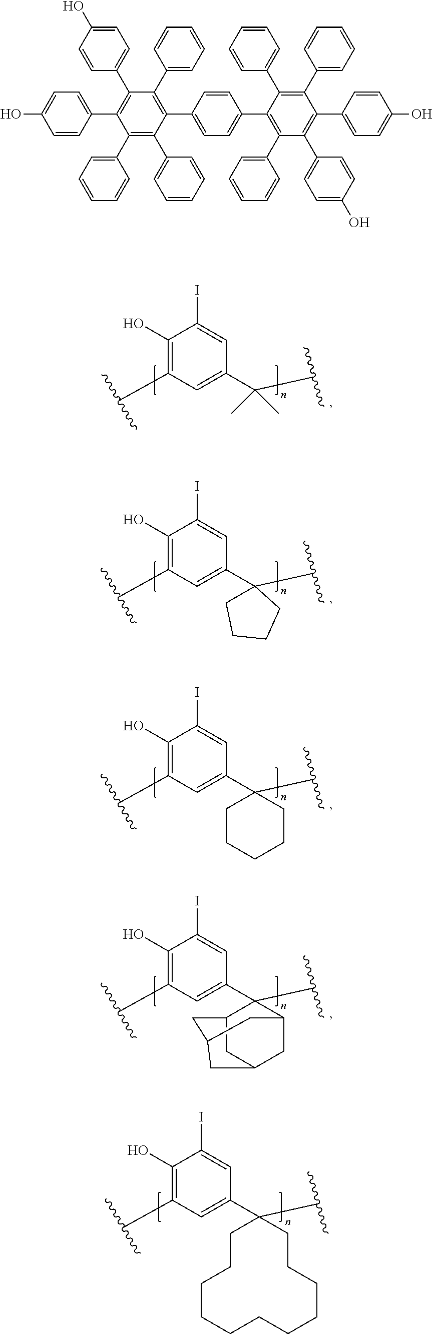

Molecule C3 is represented by formula C3. Molecule C3 can work as unit to constitute polymer of high-carbon material (C).

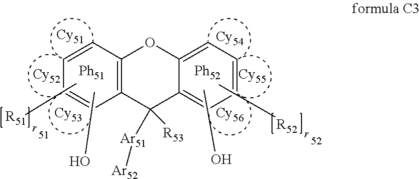

Ar₅₂ is a single bond, C₁₋₆ alkyl, C₆₋₁₂ cycloalkyl, or C₆₋₁₄ aryl. Ar₅₁ is preferably a single bond, C₁₋₆ alkyl, or phenyl; more preferably a single bond, linear C₃ alkyl, linear C₆ alkyl, tertiary butyl, or phenyl; further preferably a single bond or phenyl; further, more preferably, phenyl.

Ar₅₂ is C₁₋₆ alkyl, C₆₋₁₂ cycloalkyl, or C₆₋₁₄ aryl. Ar₅₂ is preferably isopropyl, tertiary butyl, C₆ cycloalkyl, phenyl, naphthyl, phenanthryl, or biphenyl; more preferably phenyl.

R₅₁ and R₅₂ are each independently C₁₋₆ alkyl, hydroxy, halogen, or cyano. Each independently R₅₁ and R₅₂ are preferably methyl, ethyl, propyl, isopropyl, tertiary butyl, hydroxy, fluorine, chlorine, or cyano; more preferably methyl, hydroxy, fluorine, or chlorine.

R₅₃ is hydrogen, C₁₋₆ alkyl, or C₆₋₁₄ aryl. R₅₃ is preferably hydrogen, C₁₋₆ alkyl, or phenyl; more preferably hydrogen, methyl, ethyl, linear C₅ alkyl, tertiary butyl, or phenyl; further preferably hydrogen or phenyl; further, more preferably, hydrogen.

In the case that Ar₅₂ is C₁₋₆ alkyl or C₆₋₁₄ aryl and R₅₃ is C₁₋₆ alkyl or C₆₋₁₄ aryl, Ar₅₂ and R₅₃ may bond each other to form a hydrocarbon ring.

r₅₁ and r₅₂ are each independently integer of 0-5. Each independently r₅₁ and r₅₂ are preferably 0 or 1; more preferably 0.

Optionally and each independently Cy₅₁, Cy₅₂ and Cy₅₃ rings surrounded by broken lines can be aromatic hydrocarbon ring fused with the adjacent aromatic hydrocarbon ring Ph₅₁.

Optionally and each independently Cy₅₄, Cy₅₅ and Cy₅₆ rings surrounded by broken lines can be aromatic hydrocarbon ring fused with the adjacent aromatic hydrocarbon ring Ph₅₂.

The bonding positions of R₅₁, R₅₂ and OH are not limited.

Below compound is exemplified embodiment Molecule C3 of the invention. The aromatic hydrocarbon ring Ph₅₁ and the aromatic hydrocarbon ring Cy₅₃ are fused each other to form a naphthyl ring, and OH is bonded to the aromatic hydrocarbon ring Cy₅₃. Further, Ar₅₁ is a single bond, Ar₅₂ and R₅₃ are phenyl, and Ar₅₂ and R₅₃ bond each other to form a hydrocarbon ring (fluorene).

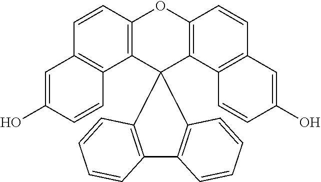 [SMILES: Oc1ccc2c3c(ccc2c1)Oc1ccc2cc(O)ccc2c1C31c2ccccc2-c2ccccc21]

Exemplified molecule C3s are described below, without intent to limit the scope of the invention.

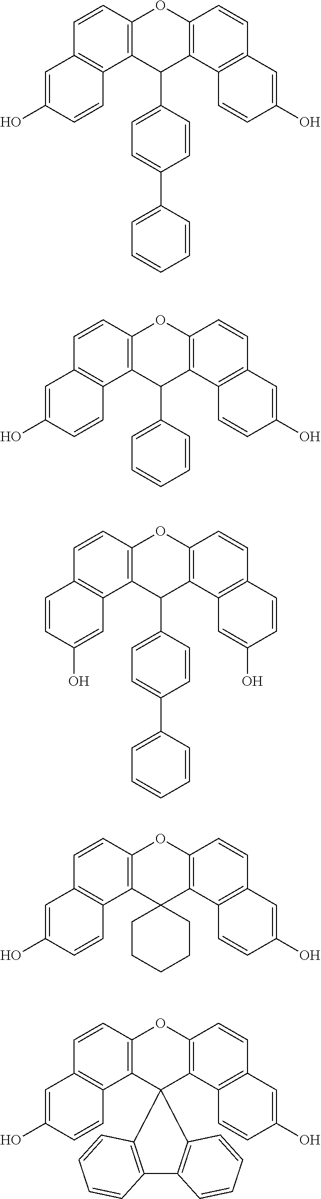

Unit C4 is represented by formula C4.

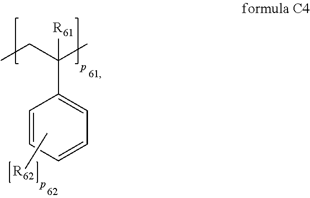

R₆₁ is hydrogen, C₁₋₆ alkyl, halogen, or cyano; preferably hydrogen, methyl or t-butyl; more preferably hydrogen or methyl; further preferably hydrogen.

R₆₂ is C₁₋₆ alkyl, halogen, or cyan; preferably methyl or t-butyl; more preferably methyl.

p₆₁ is repeating number. p₆₂ is integer of 0-5; preferably 0-1; more preferably 0.

As one aspect of the invention, high-carbon material (C) can comprise plural species of unit C2, molecule C3 and unit C4. Such exemplified embodiments are described below, without intent to limit the scope of the invention.

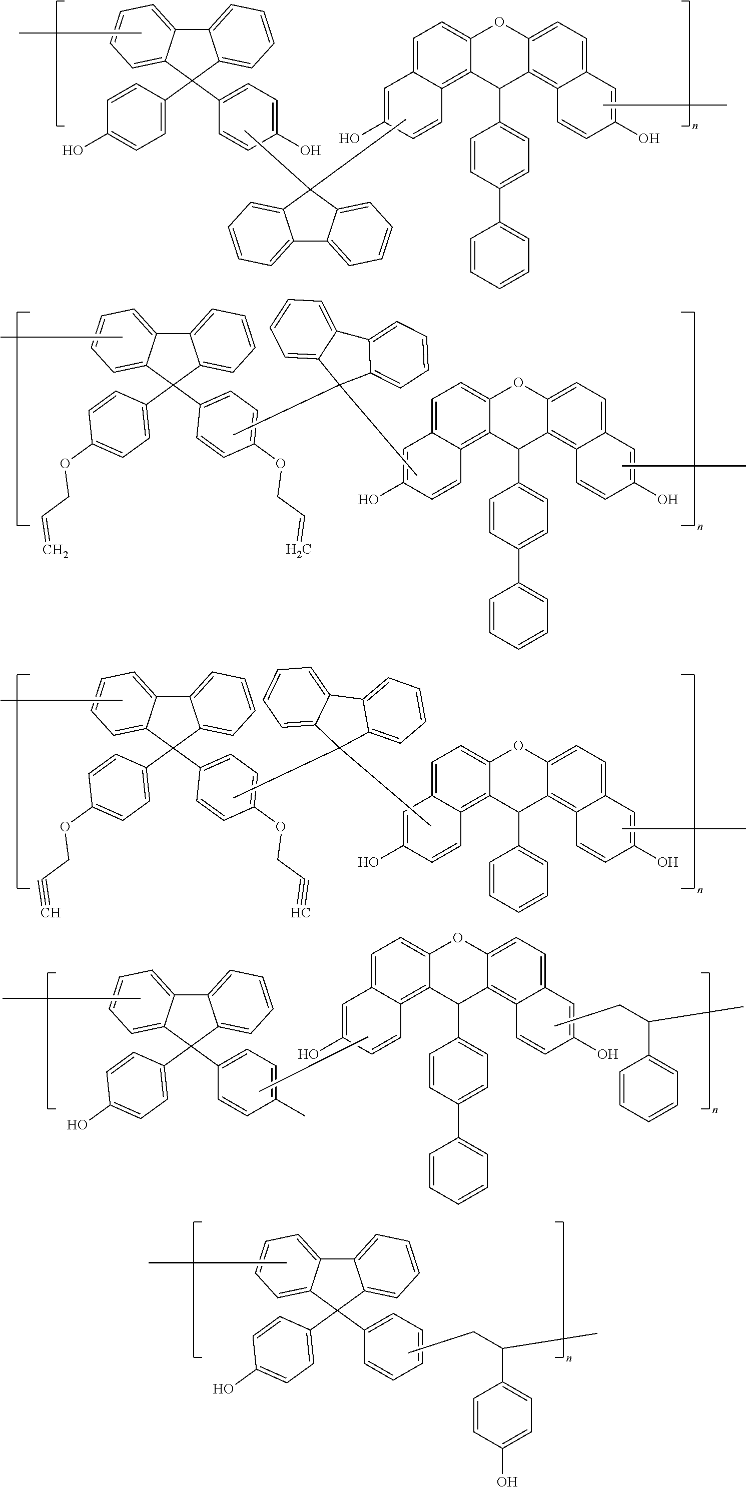

In one embodiment of the invention the mass ratio of said high-carbon material (C) is based on the total mass of segregating composition is 0.5-30 mass %; preferably 1-20 mass %; more preferably 3-15 mass %; further preferably 5-10 mass %; further, more preferably 5-8 mass %.

Thermal Acid Generator (D)

The composition used in the manufacturing method of the invention can comprise thermal acid generator (D) and/or cross linker (E). By heating, thermal acid generator (TAG) can generate an acid; preferably strong acid.

Generated acid can catalyze reactions of crosslinker (E) and can help processing at lower temperature and shorten reaction time to form the anti-reflective coating.

Preferred TAGs are those which are activated at a temperature exceeding 80 degrees. Examples of the TAG include metal-free sulfonium salts and metal-free iodonium salts, for example, triarylsulfonium, dialkylarylsulfonium and diarylalkylsulfonium salts of strong non-nucleophilic acids, and alkylaryliodonium and diaryliodonium salts of strong non-nucleophilic acids; and ammonium, alkylammonium, dialkylammonium, trialkylammonium, and tetraalkylammonium salts of strong non-nucleophilic acids.

Further, covalent TAGs are also useful, and examples thereof include 2-nitrobenzyl esters of alkyl or aryl sulfonic acids and other sulfonic acid esters which are thermally decomposed to give free sulfonic acid. Examples thereof include diaryliodonium perfluoroalkyl sulfonates, diaryliodonium tris(fluoroalkylsulfonyl)methides, diaryliodonium bis(fluoroalkylsulfonyl)methides, diaryliodonium bis(fluoroalkylsulfonyl)imides, and diaryliodonium quaternary ammonium perfluoroalkyl sulfonates. Examples of labile esters include 2-nitrobenzyl tosylate, 2,4-dinitrobenzyl tosylate, 2,6-dinitrobenzyl tosylate, and 4-nitrobenzyl tosylate; benzenesulfonates such as 2-trifluoromethyl nitrobenzyl 4-chlorobenzenesulfonate and 2-trifluoromethyl-6-nitrobenzyl 4-nitrobenzenesulfonate; phenolic sulfonate esters such as phenyl 4-methoxybenzenesulfonate; quaternary ammonium tris(fluoroalkylsulfonyl)methides, quaternary alkylammonium bis(fluoroalkylsulfonyl)imides, and alkylammonium salts of organic acids such as triethylammonium salt of 10-camphorsulfonic acid. Various aromatic (anthracene, naphthalene, or benzene derivative) sulfonic acid amine salts can be used as the TAG.

Exemplified embodiments of TAGs (D) are described below, without intent to limit the scope of the invention.

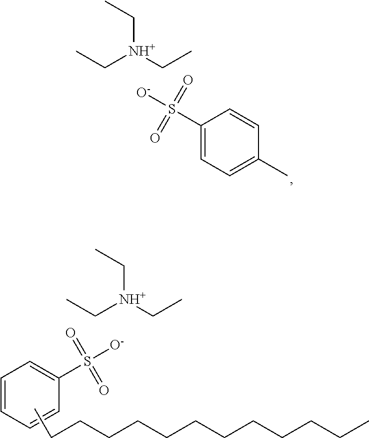

In one embodiment of the invention the mass ratio of said thermal acid generator (D) is based on the total mass of said siloxane polymer (B) is 10-50 mass %; preferably 10-40 mass %; more preferably 15-30 mass %; further preferably 20-30 mass %.

Cross Linker (E)

The cross linker (E) can increase the coating formation property and can prevent the segregated layers of the invention from being intermixed with the upper coating (such as a resist coating), and to eliminate diffusion of low molecular weight components into the upper coating. By heating, cross linker (E) can bond to high-carbon material (C) to make spin-on-carbon coating.

As the cross linker (E), melamine compounds, guanamine compounds, glycoluril compounds or urea compounds substituted by at least one group selected from a methylol group, an alkoxymethyl group, and an acyloxymethyl group; epoxy compounds; thioepoxy compounds; isocyanate compounds; azide compounds; and compounds comprising a double bond such as an alkenyl ether group can be used. These may be used as an additive or may be introduced as a pendant group into a polymer side chain. Further, compounds comprising a hydroxy group can also be used as a cross linker.

Examples of the epoxy compounds mentioned above include tris(2,3-epoxypropyl)isocyanurate, trimethylolmethane triglycidyl ether, trimethylolpropane triglycidyl ether, and triethylolethane triglycidyl ether. Examples of the melamine compounds include hexamethylolmelamine, hexamethoxymethylmelamine, compounds derived by methoxymethylation of 1-6 methylol groups of hexamethylolmelamine and mixtures of such compounds, hexamethoxyethylmelamine, hexaacyloxymethylmelamine, compounds derived by acyloxymethylation of 1-6 methylol groups of hexamethylolmelamine or mixtures of such compounds. As the guanamine compounds, tetramethylolguanamine, tetramethoxymethylguanamine, compounds derived by methoxymethylation of 1-4 methylol groups of tetramethylolguanamine and mixtures of such compounds, tetramethoxyethylguanamine, tetraacyloxyguanamine, compounds derived by acyloxymethylation of 1-4 methylol groups of tetramethylolguanamine and mixtures of such compounds can be used. As the glycoluril compounds, tetramethylolglycoluril, tetramethoxyglycoluril, tetramethoxymethylglycoluril, compounds derived by methoxymethylation of 1-4 methylol groups of tetramethylolglycoluril or mixtures of such compounds, compounds derived by acyloxymethylation of 1-4 methylol groups of tetramethylolglycoluril or mixtures of such compounds can be used. As the urea compounds, tetramethylolurea, tetramethoxymethylurea, compounds derived by methoxymethylation of 1-4 of methylol groups of tetramethylolurea or mixtures of such compounds, and tetramethoxyethylurea, and the like can be used.

As the compounds containing an alkenyl ether group, ethylene glycol divinyl ether, triethylene glycol divinyl ether, 1,2-propanediol divinyl ether, 1,4-butanediol divinyl ether, tetramethylene glycol divinyl ether, neopentyl glycol divinyl ether, trimethylolpropane trivinyl ether, hexanediol divinyl ether, 1,4-cyclohexanediol divinyl ether, pentaerythritol trivinyl ether, pentaerythritol tetravinyl ether, sorbitol tetravinyl ether, sorbitol pentavinyl ether, trimethylolpropane trivinyl ether, and the like can be used.

Exemplified embodiments of cross linker (E) are described below, without intent to limit the scope of the invention.

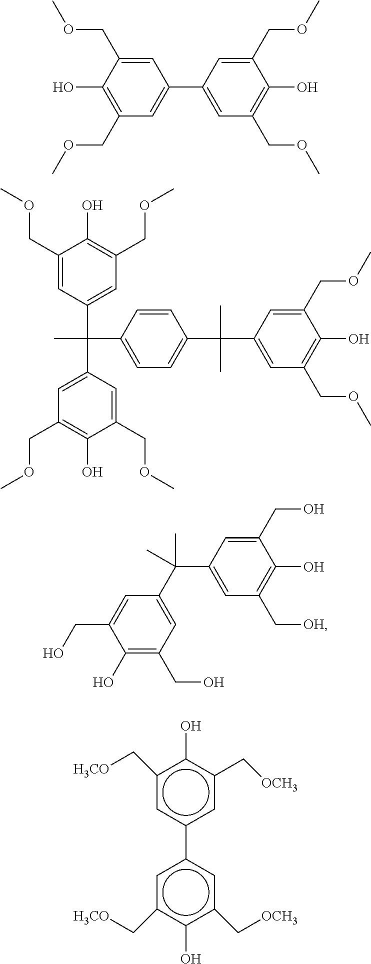

In one embodiment of the invention the mass ratio of said cross linker (E) is based on the total mass of said high-carbon material (C) is 3-50 mass %; preferably 5-30 mass %; more preferably 5-20 mass %; further preferably 8-15 mass %.

Additive (F)

The composition used in the manufacturing method of the invention can comprise further additive (F) other than a TAG (D) or a cross linker (E). Such additive can comprise a surfactant, a thermal base generator (TBG), acid, base, a photopolymerization initiator, an agent for enhancing the adhesion to substrates, or any mixture of any of these.

In one embodiment of the invention the mass ratio of said additive (F) (if there are plural species, sum of them) is based on the total mass of segregating composition is 0-10 mass %; preferably 0.0001-5 mass %; more preferably 0.0001-3 mass %. In another aspect of the invention the additive (F) is not contained in the segregating composition.

Surfactant

Surfactant is one embodiment of additive (F). A surfactant can decrease pin hole or striation in a coating made by the composition, and can increase the coatability and/or solubility of the composition.

The amount of the surfactant is preferably 0-5 mass %; more preferably 0.00001-3 mass %; further preferably 0.0001-2 mass %; and further, more preferably 0.001-2 mass %. In another preferable embodiment of the invention the composition does not comprise any surfactant (0 mass %). Examples of the surfactant include: polyoxyethylene alkyl ether compounds such as polyoxyethylene lauryl ether, polyoxyethylene stearyl ether, and polyoxyethylene oleyl ether; polyoxyethylene alkylaryl ether compounds such as polyoxyethylene octylphenol ether and polyoxyethylene nonylphenol ether; polyoxyethylene-polyoxypropylene block copolymer compounds; sorbitan fatty acid ester compounds such as sorbitan monolaurate, sorbitan monopalmitate, sorbitan monostearate, sorbitan trioleate, and sorbitan tristearate; and polyoxyethylene sorbitan fatty acid ester compounds such as polyoxyethylene sorbitan monolaurate, polyoxyethylene sorbitan monopalmitate, polyoxyethylene sorbitan monostearate, and polyoxyethylene sorbitan tristearate. Other examples of the surfactant include: fluorosurfactants such as EFTOP (trade name) EF301, EF303, and EF352 (Tohkem Products Corporation), MEGAFACE (trade name) F171, F173, R-08, R-30, R-41 and R-2011 (DIC Corporation), Fluorad FC430 and FC431 (Sumitomo 3M), AsahiGuard (trade name) AG710 (Asahi Glass), and SURFLON S-382, SC101, SC102, SC103, SC104, SC105, and SC106 (Asahi Glass); and organosiloxane polymers such as KP341 (Shin-Etsu Chemical).

Method of Manufacturing Segregated Layers

This invention provides a method of manufacturing segregated layers above a substrate, comprising: (1) applying a composition above said substrate, wherein said segregated composition comprises solvent (A), siloxane polymer (B) and high-carbon material (C); and (2) heating said substrate to form segregated layers of antireflective coating made from siloxane polymer (B) and spin-on-carbon coating made from high-carbon material (C), where placed said antireflective coating, spin-on-carbon coating and substrate in this order.

It is described for clarity that, in the process description, the number between brackets means order throughout this specification, unless specifically stated. For example, (1) step is carried out before (2) step.

Not wishing to be bound by the theory, but inventors think that the phase separation is driven through surface energy differences and/or solubility difference between the siloxane polymer (B) and the high-carbon material (C). One aspect of the invention is that the self-segregation is caused by phase separation by surface energy difference and/or solubility difference (preferably by surface energy difference) of siloxane polymer (B) and high-carbon material (C).

The segregating composition of the invention can be applied above a substrate. The term “above a substrate” may denote that the applied composition can form coating directly on the substrate, i.e. in direct contact with the substrate, but also include that an interlayer may be interposed between the substrate and the applied composition. The term of “above” comprise “direct contact with” and “intervened by an intervening layer(s)”.

Before this, the substrate surface can be pre-treated, for example by 1,1,1,3,3,3-hexamethyldisilazane solution. The upper surface of the substrate can be flat or not-flat. The substrate used can be a metal-containing substrate or a silicon-containing substrate. The substrate may be a single-layer substrate, or a multi-layer substrate composed of a plurality of substrate layers. As the substrate there can be used any known substrate such as a silicon-coated substrate.

As one embodiment of the invention, the segregating composition is applied by an appropriate measure such as a spinner or coater. In the application of the composition to the substrate, it is preferable for the substrate and the composition to come into direct contact with each other. It is also another embodiment of the invention that the segregating composition may be applied with another thin coating (such as a substrate-modifying layer) interposed between the segregating composition and the substrate. The application of the composition is followed by heating to occur phase separation to segregate layers of antireflective coating and spin-on-carbon coating.

The (2) heating of the invention is carried out typically 20-450° C. for 0.1-30 min. Preferably the heating is carried out in an air atmosphere, inert gas, or combination of them.

For phase separation which require long times, heating is preferable. Several heating steps are preferable for this aspect. As a first heating step, low temperature heating is preferable. As one example of the invention, under air vacuumed condition, the substrate is heated at low temperature; preferably room temperature to 80 C degree; more preferably at 50-80 C degree; further preferably at 50-75 C degree. The heating time of first heating step is selected from the range of 30-240 seconds (preferably 60-180 seconds, more preferably at 90-150 seconds).

A preferable embodiment of the invention is that the heating comprises multiple heating step. For example, second heating step, third heating step; fourth heating step can be added. Heating conditions for four steps are exemplified as follows. All the heating steps are not always necessary to enable this invention and can be simplified in terms of high throughputs. In a more preferable embodiment of the invention the heating consists of two step bakes, which are a first heating step and a second heating step.

The second heating step can be carried out at 50-250 C degree (preferably 75-200 C degree; more preferably 100-200 C degree; further preferably 125-175 C degree) for 0.5-30 min (preferably 1-20 min; more preferably 5-15 min).

The third heating step can be carried out at 100-400 C degree (preferably 150-300 C degree; more preferably 200-300 C degree; further preferably 225-275 C degree) for 0.1-5 min (preferably 0.1-3 min; more preferably 0.5-2 min).

The fourth heating step can be carried out at 150-450 C degree (preferably 250-400 C degree; more preferably 300-400 C degree; further preferably 325-375 C degree) for 0.1-5 min (preferably 0.1-3 min; more preferably 0.5-2 min).

Later heating step tends to have high temperature. Spin-on-carbon coating made from high-carbon material (C) of the invention can exhibit good heat tolerance. So, it's possible to carry out high temperature heating in this method.

In one embodiment of the invention the antireflective coating is made from a siloxane polymer (B) which has a 50-500 nm thickness; preferably 50-200 nm; more preferably 100-200 nm. In one embodiment of the invention the spin-on-carbon coating is made from a high-carbon material (C) which has 100-10,000 nm thickness; preferably 100-1,500 nm; more preferably 100-1,000 nm; further preferably 100-500 nm; further, more preferably 100-200 nm.

It is supported that siloxane polymer (B) has a structure available to become a coating exhibit favorable anti-reflective index. So, the coating is available to work as antireflective coating; preferably bottom antireflective coating. While not wishing to be bound by theory, the inventors think that upper interface made from the segregating composition is silicon rich, so main components near the upper interface are coating made from siloxane polymer (B). Thus, the coating made from the segregating composition is available to work as a bottom antireflective coating.

In one embodiment of the invention the coating is made from the composition of the invention which has 150-2,000 nm thickness (preferably 150-1,000 nm; more preferably 150-500 nm; further preferably 150-200 nm) as sum of the antireflective coating and spin-on-carbon coating. Both antireflective coating made from siloxane polymer (B) and spin-on-carbon coating made from high-carbon coating are available to exhibit favorable etch resistance. The segregating layers are available to exhibit good etch resistance. It is possible to change atom contents of spin-on-carbon coting by modifying high-carbon material (C) and other solid components, then making available to obtain a favorable etch rate for the process in which this segregating composition is used. Solid components including high-carbon material (C) can exhibit good gap filing property, then making available to apply this segregating composition onto not-flat substrate.

Formation of Photoresist Layer

This invention also provides manufacturing method of photoresist layer comprising (3) applying a photoresist composition above the said segregated layers, and (4) heating said substrate to form photoresist layer.

A photoresist composition is applied above the segregated layers manufactured as above. The term “above the segregated layers” may denote that the applied photoresist composition can form layer directly on the segregated layers, i.e. in direct contact with the segregated layers on upper side, but also include that an interlayer may be interposed between the upper side of segregated layers and the applied photoresist composition. Preferably the applied photoresist composition form layer directly on the segregated layers.

A known method can be used for the application, for example spin coating. And the applied photoresist composition is heated to remove the solvent in the composition, thereby forming a photoresist layer. The heating temperature can vary depending on the composition to be used, but is preferably 70-150° C. (more preferably 90-150° C., further preferably 100-140° C.). It can be carried out for 10-180 seconds, preferably for 30-90 seconds in the case of on a hot plate, or for 1 to 30 minutes in case of in a hot gas atmosphere (for example in a clean oven). The formed photoresist layer has a thickness of 0.40-5.00 μm preferably (0.40-3.00 μm more preferably, 0.50-2.00 μm further preferably).

Formation of Photoresist Pattern

This invention provides a manufacturing method of photoresist patterns comprising (5) exposing the said photoresist layer, and (6) developing said exposed layer to form photoresist pattern.

The photoresist layer undergoes a reaction under light/irradiation exposure. Both positive tone photoresist and negative tone photoresist can be used. In positive tone photoresist layer, irradiated portion will increase solubility to a developer. Other layer(s) (for example, TARC) may be formed on the photoresist layer.

The photoresist layer is exposed through a given mask. The wavelength of the light used for exposure is not particularly limited. The exposure is preferably performed with light having a wavelength of 13.5-365 nm (preferably 13.5-248 nm). KrF excimer laser (248 nm), ArF excimer laser (193 nm), or extreme ultraviolet light (13.5 nm) are preferred embodiments; KrF excimer laser is more preferred. These wavelengths may vary within ±1%.

The exposure can, if desired, be followed by heating, also called a post-exposure bake (PEB). The temperature for the PEB is selected from the range of 80-150° C., preferably 90-140° C., and the heating time for the PEB is selected from the range of 0.3-5 minutes, preferably 0.5-2 minutes. Next, development is performed with a developer. In the positive tone photoresist layer, unexposed portions are removed by the development, resulting in the formation of resist patterns. A 2.38 mass % (+1% concentration change accepted) aqueous TMAH solution is one exemplified example as developer, but without intent to limit the scope of the invention. An additive such as a surfactant can be added to the developer. The temperature of the developer is typically selected from the range of 5-50° C., preferably 25-40° C., and the development time is typically selected from the range of 10-300 seconds, preferably 30-90 seconds. As the developing method, known methods such as paddle development can be used. After development, the resist patterns can be cleaned by water or cleaning solution as replacing developer with the water and/or cleaning solution. Then, the patterns can be dried, for example by a spin-dry method.

Etching

This invention provides a manufacturing method of processed substrate comprising (7) etching through the above said resist pattern as a mask, and (8) processing the substrate. This etching can form patterns of interposed layer and/or substrate. A known etching method can be used for example, dry etching and wet etching (preferably dry etching). The term “interposed layer” mean layer between resist patterns and the substrate, which comprises segregated layers, antireflective coating, and spin-on-carbon coating. The obtained patterns of interposed layer can be used as a next mask to process further below layer or substrate. Another aspect of the invention provides that the patterns of photoresist can be used as a mask to process segregated layers and the substrate at one time etching.

It is possible to forming a wiring(s) in the processed substrate. Remained layer/patterns above the substrate can be removed by a known method, for example dry etching of O₂, CF₄, CHF₃, Cl₂ or BCl₃; preferably O₂ or CHF₃.

As one embodiment of the invention, it is preferable to etch antireflective coating with CF₄ or CHF₃ (more preferably CHF₃), and then change etch gas to O₂ to etch spin-on-carbon coating.

Device Manufacturing

Subsequently, the substrate, if necessary, is further processed to form a device. Such further processing can be done by using a known method. After formation of the device, the substrate, if necessary, is cut into chips, which are connected to a leadframe and packaged with a resin. Preferably the device is a semiconductor device, solar cell chip, organic light emitting diode and inorganic light emitting diode. One preferable embodiment of the device of this invention is a semiconductor device.

### EXAMPLES

Hereinafter, the present invention will be described with working examples. These examples are given only for illustrative purpose and are not intended to limit the scope of the present invention. The term “part(s)” as used in the following description refers to part(s) by mass, unless otherwise stated.

A Tokyo Electron Clean Track Act 8 was used for coating and baking of samples.

The weight average molecular weight (Mw) and number average molecular weight (Mn) of the polymers were measured by Gel Permeation Chromatography (GPC) calibrated with polystyrene standards and polydispersity (Mw/Mn) was calculated therefrom.

### Preparation Example 1 of Working Composition 1

Polymer C2-1 was made same manner as described in U.S. Pat. No. 9,274,426 (Synthesis of Polymer 1). Formulations were prepared by dissolution of below 3 materials in a PGMEA and PGME solvent mixture. The formulation was heated to 50° C. and stirred for 4 hours.

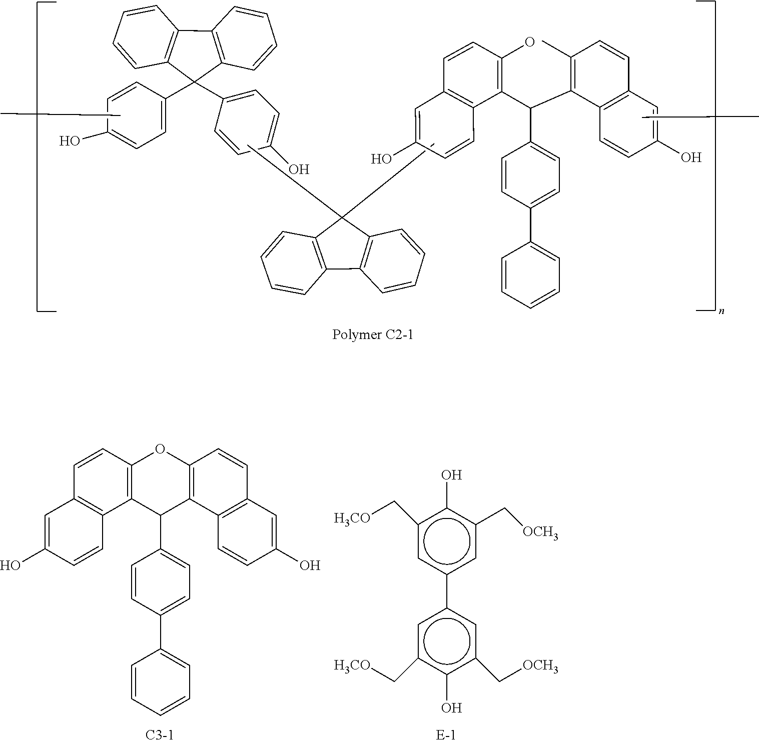

10% D-1 was prepared by dissolving decylbenzenesulfonic acid and triethyamine in PGMEA and PGME mixture. This was not heated but stirred for 10 mins. This 10% D-1 was then added into the other above solution when both were at room temperature.

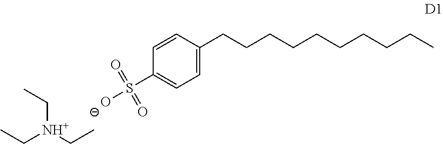

The Di(PGMEA) and n-decyl acetate was then added to the solution and the Siloxane polymer 1 was added. The solution was then heated to 50° C. for 1 hour. It was confirmed visually that solutes were dissolved. Once the formulation has cooled it was filtered through a 0.2 μm polypropylene filter to obtain working composition 1.

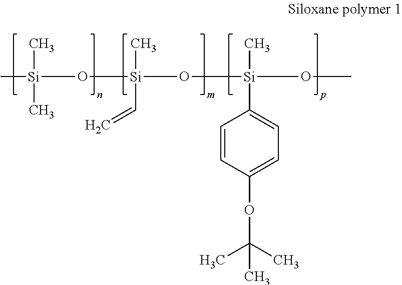

Mass percentage of each components and solvents in the solution were described in the below Table 1.

TABLE 1

| Material | Percentage |
|---|---|
| Polymer C2-1 | 4.49% |
| C3-1 | 2.16% |
| E-1 | 0.66% |
| D-1 | 0.27% |
| PGMEA | 56.17% |
| PGME | 23.86% |
| n-decyl acetate | 3.98% |
| Di(PGMEA) | 7.95% |
| Siloxane polymer 1 | 0.46% |
| Total | 100.00% |

### Preparation Example 2-7 of Working Composition 2-7

Preparations were carried out in the same manners as in Preparation Example 1, except for changing Siloxane polymer 1 to Siloxane polymer 2, 3, 4, 5, 6 and 7 to obtain working composition 2, 3, 4, 5, 6 and 7.

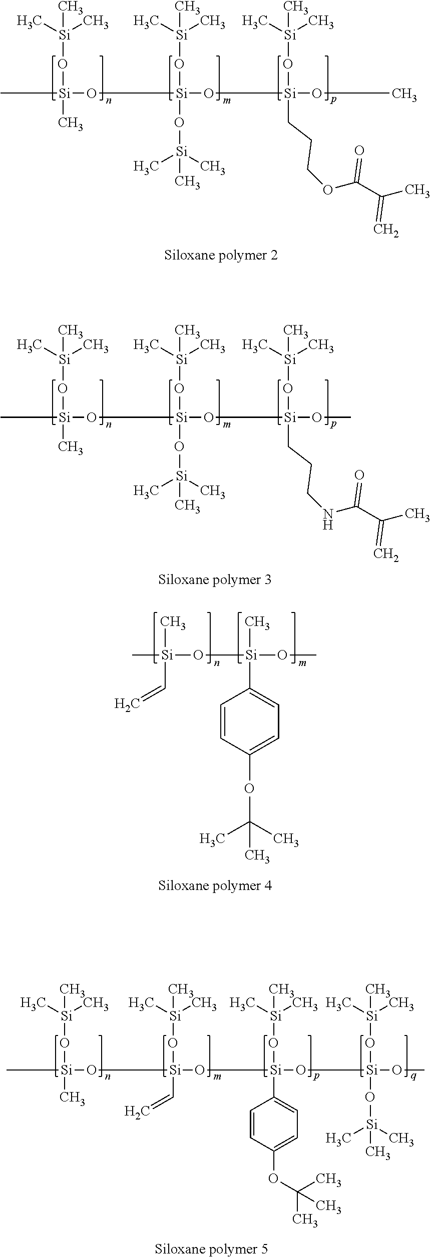

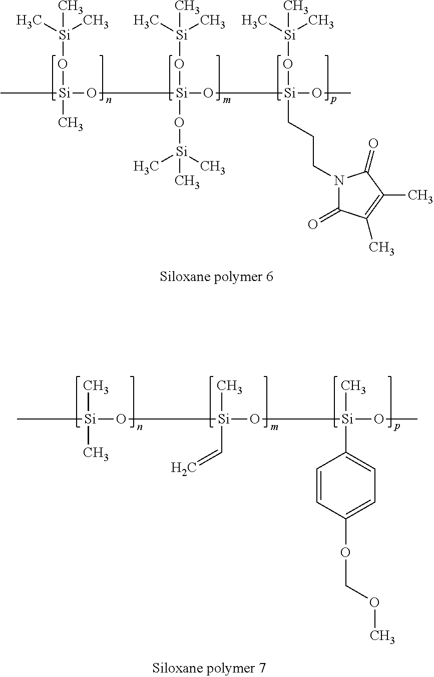

Synthesis Chemistry of Siloxane Polymer 2

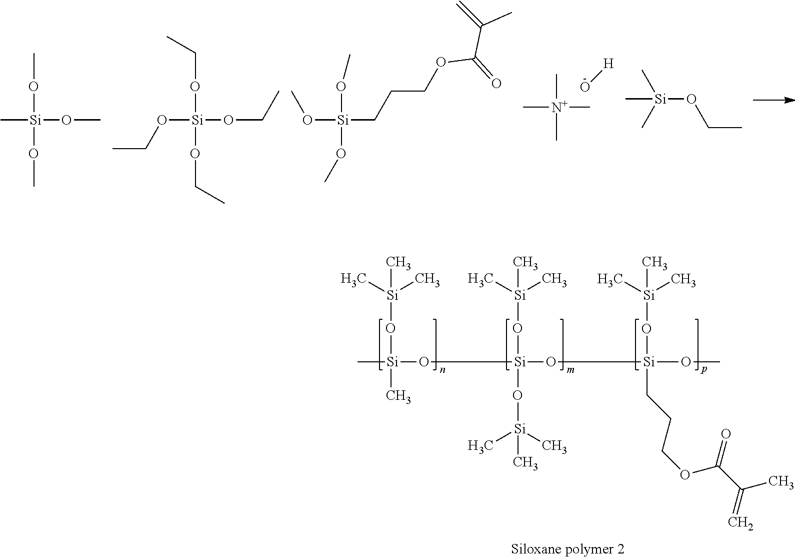

Trimethoxy(methyl)silane (3.178 g; 23.330 mmol; 1.00 eq.), tetraethyl orthosilicate (3.646 g; 17.500 mmol; 0.75 eq.), 3-(trimethoxysilyl)propyl methacrylate (4.346 g; 17.500 mmol; 0.75 eq.) and propan-2-ol (13.000 g; 216.324 mmol; 9.27 eq.) were directly weighed (in air) in to a 100 mL 3-neck RBF (Round-bottom flask). The mixture was stirred in an ice-water bath till the temperature was 0°. Tetramethylammonium hydroxide 25% aqueous solution (4.120 g; 11.300 mmol; 0.48 eq.) was added by portions within about 2 minutes. The reaction was slightly exothermic. The temperature increases to 10° C. after the addition. Once the addition was completed, the ice-water bath was removed. The solution was stirred at 25° C. (external) for 2 hours. The mixture remained as a clear colorless solution. Ethoxytrimethylsilane (5.000 ml; 31.493 mmol; 1.35 eq.) was added and the mixture was stirred for an additional 2 hours at 25° C.

A conical flask (100 mL) was charged with deionized water (33.6 g), Hydrochloric acid (32%, 1.200 g; 11.519 mmol; 0.49 eq.), and n-propyl acetate (16.800 g; 164.493 mmol; 7.05 eq.). The reaction mixture in the RBF (a clear colorless solution) was decanted into the conical flask with stirring at 1,000 rpm to yield a white turbulent solution. The mixture was stirred for 30 min. The mixture was transferred into a separation funnel; and a waiting time of 10 minutes was allowed until complete phase separation occur. The polymer was in the upper organic phase. The upper organic layer was slightly white milky. The bottom aqueous phase was separated and discarded (pH=1). Deionized water (33.6 g) was added to the organic phase and shaken well. N-Propyl acetate (6.5 g) was added and the mixture was shaken then left overnight. The separation was not achieved. 6.5 g of isopropyl alcohol was added. The bottom layer was removed and discarded. The wash process was repeated for another time till the pH was 7.

The organic phase was rotary-evaporated first till 80 mbar followed by the addition of PGMEA 10 g. The mixture was further rotary-evaporated till 23 mbar to end-up as a clear colorless solution (13.5 g). The solution was filtered through a syringe 0.45 μm filter as precaution. Molecular weights were determined by GPC eluted with THF (tetrahydrofuran). Solid content (150 C, 30 min) was measured to be 48.4%

| Mn | Mw | Mw/Mn |
|---|---|---|
| 2426 | 5159 | 2.13 |

Synthesis Chemistry of Siloxane Polymer 3

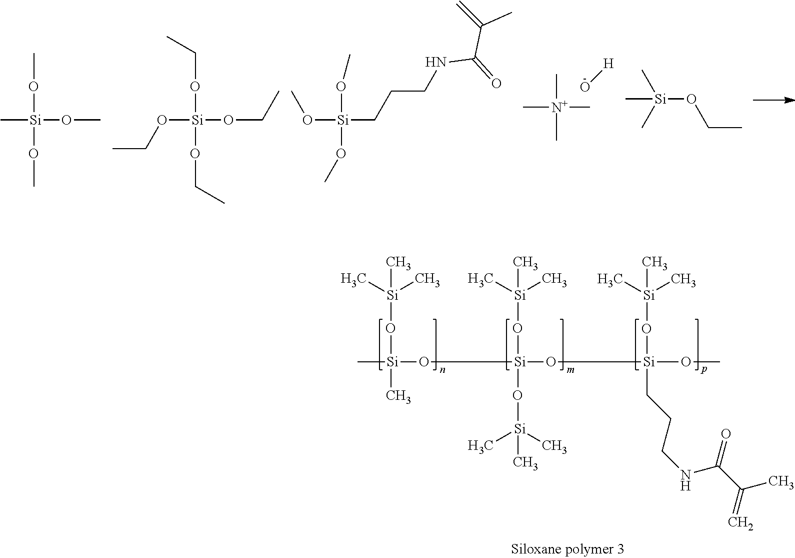

Trimethoxy(methyl)silane (3.178 g; 23.330 mmol; 1.00 eq.), tetraethyl orthosilicate (3.646 g; 17.500 mmol; 0.75 eq.), 2-methyl-N-[3-(trimethoxysilyl)propyl]prop-2-enamide (4.329 g; 17.500 mmol; 0.75 eq.) and propan-2-ol (13.000 g; 216.324 mmol; 9.27 eq.) were directly weighed (in air) in to a 100 mL 3-neck round-bottomed flask. The mixture was stirred in an ice-water bath at 600 rpm till the temperature was 0° C. (internal temperature). Tetramethylammonium hydroxide 25% aqueous solution (4.120 g; 11.300 mmol; 0.48 eq.) was added by portions within about 2 minutes. The solution was stirred with the cooling bath for 15 min before the cooling bath was removed. The reaction was continued at room temperature for an additional 1 h 45 min. The mixture remains as a clear colorless solution (slightly pale-yellow).

Ethoxytrimethylsilane (5.000 ml; 31.493 mmol; 1.35 eq.) was added and the mixture was stirred for an additional 4 hours at 25° C. A conical flask (100 mL) was charged with deionized water (33.6 g), hydrochloric acid (32%, 1.200 g; 11.519 mmol; 0.49 eq.), and n-Propyl acetate (16.800 g; 164.493 mmol; 7.05 eq.). The reaction mixture in the RBF (a clear colorless solution) was decanted into the conical flask with stirring at 1,000 rpm to yield a white turbulent solution. The mixture was stirred for 30 min then transferred into a separation funnel. Wait 10 minutes until complete phase separation occur. The bottom aqueous phase was separated and discarded (pH=5). Deionized water (33.6 g) was added to the organic phase and shaken well. The bottom later was removed and discarded (pH 7).

The organic phase was rotary-evaporated first till 80 mbar followed by the addition of PGMEA 9 g. The mixture was further rotary-evaporated till 23 mbar to end-up as a clear colorless solution (14.5 g). The solution was filtered through a syringe 0.45 μm filter as precaution. Solid content (150 C, 30 min) was 54%. Molecular weights were determined by GPC eluted with THF.

| Mn | Mw | Mw/Mn |
|---|---|---|
| 1762 | 2633 | 1.49 |

Synthesis Chemistry of Siloxane Polymer 6

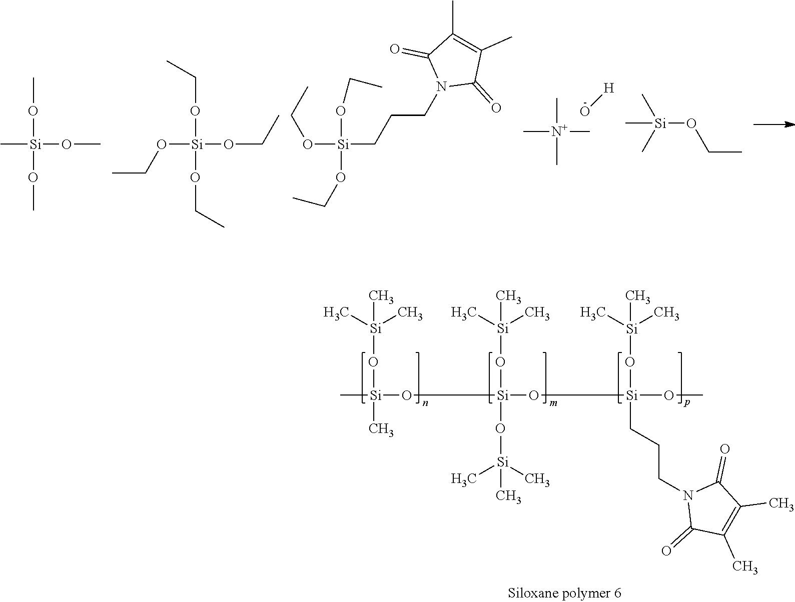

Trimethoxy(methyl)silane (2.724 g; 20.000 mmol; 1.00 eq.), tetraethyl orthosilicate (1.042 g; 5.000 mmol; 0.25 eq.), 3,4-dimethyl-1-(3-triethoxysilylpropyl)pyrrole-2,5-dione (8.237 g; 25.000 mmol; 1.25 eq.) and propan-2-ol (13.000 g; 216.324 mmol; 10.82 eq.) were directly weighed (in air) in to a 100 ml 3-neck RBF. The mixture was stirred in an ice-water bath at 600 rpm till the temperature was 5° C. (internal temperature).

Tetramethylammonium hydroxide (25% aqueous solution, 4.120 g; 11.300 mmol; 0.56 eq.) was added dropwise within 3 minutes. The reaction was slightly exothermic, and the temperature increase by 5 degree to 100 after the addition. Once the addition was completed, the ice-water bath was removed. The colorless solution stabilizes at 18° C. and was stirred for 2 hours. Ethoxytrimethylsilane (5.000 ml; 31.493 mmol; 1.57 eq.) was added all at once at room temperature. The solution was stirred for an additional 2 hours.

A conical flask (100 ml) was charged with deionized water (33.6 g), hydrochloric acid (32%, 1.240 g; 11.903 mmol; 0.60 eq.), and n-propyl acetate (16.800 g; 164.493 mmol; 8.22 eq.). The reaction mixture in the RBF (a clear colorless solution) was decanted into the conical flask with stirring at 1,000 rpm to yield a white turbulent solution. The mixture was stirred for 0.5 hour then was transferred into a separation funnel. Wait 20 minutes until complete phase separation occur. The polymer was in the upper organic phase. The bottom aqueous phase was separated and discarded (pH=6). Deionized water (33.6 g) and propan-2-ol (6.5 g) were added to the organic phase and shaken well. The phase separation was achieved within 10 min. The bottom later was removed and discarded (pH 7). PGMEA (17 g) was added to the organic phase and the mixture was rotary-evaporated down to 4 mbar to end up as a pale-yellow viscous solution (10.6 g). Solid content (150 C, 30 min) was 59%. Molecular weights were determined by GPC eluted with THF.

| Mn | Mw | Mw/Mn |
|---|---|---|
| 1707 | 2490 | 1.46 |

Synthesis Chemistry of Siloxane Polymer 7

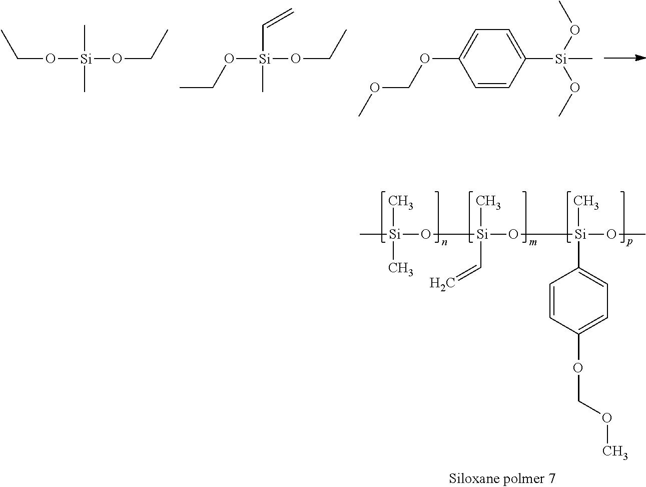

Diethoxydimethylsilane (2.966 g; 20.000 mmol; 2.00 eq.), diethoxymethylvinylsilane (3.206 g; 20.000 mmol; 2.00 eq.), and dimethoxy[4-(methoxymethoxy)phenyl]methylsilane (2.423 g; 10.000 mmol; 1.00 eq.) were directly weighed (in air) into a 25 ml round-bottomed flask. Ambersep® 900 hydroxide form (2.500 g; 27.427 mmol; 2.74 eq.) was added all at once and the mixture was stirred at 30° C. for 18 hours, 50° C. for 48 hours. The temperature was increased to 80° C. and stirred for 30 hours, followed by cooling to room temperature then addition of diethyl ether (10 ml). The mixture was filtered through a 0.45 μm syringe filter. The filtrate was rotary-evaporated to dryness to the maximum vacuum (10 mbar, 50 C) to yield a thick pale-yellow oil (3.86 g). Molecular weights were determined by GPC eluted with THF.

| Mn | Mw | Mw/Mn |
|---|---|---|
| 6764 | 17118 | 2.53 |

Substrate Preparation

Each composition was spin coated onto a CZ-Si wafer. Spin conditions were 500 rpm/10 sec then 1,500 rpm for 60 sec with acceleration speed of 500 rpm. The wafer was then heated on a hot plate at 70° C. for 2 min. The wafer was then transferred to another hotplate at 150° C. for 10 min then 250° C. for 1 min and 350° C. for 2 min.

Uniformity Evaluation

The macroscopic film uniformity was good across each Si wafer. There were no visible defects or color gradients by eye. The cross-section SEM shows no de-gassing of materials, voids or defects. The Atomic Force Microscopy imaging (AFM) shows good nanomorphology and uniform phase across 20 μm² area. Surface roughness were <2-4 nm.

Contact Angle Evaluation

Compositions listed in below table were used to evaluate contact angles. Comparative composition SOC was prepared in the same manners as in Preparation Example 1, except for without using Siloxane polymer. Substrate preparation was carried out in the same manner as described above.

The measurements use a camera to record the contact angle of drops of pure water on the surface of the coated wafer. The measurement was repeated in 6 different locations across the surface. Results show phase separations were driven to make siloxane rich interfaces come to upper surfaces.

TABLE 2

| Film made by | Contact angle (°) |
|---|---|
| Working composition 1 | 85 ± 1 |
| Working composition 2 | 82 ± 2 |
| Working composition 3 | 90 ± 2 |
| Working composition 4 | 93 ± 2 |
| Working composition 5 | 85 ± 1 |
| Working composition 6 | 92 ± 1 |
| Comparative composition SOC | 69 ± 5 |

Silicon Content Evaluation

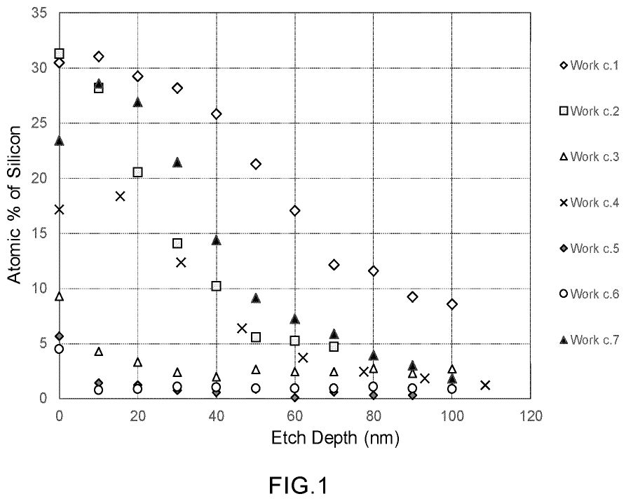

Each substrate was used to evaluate silicon content by X-ray Photoelectron Spectroscopy (XPS). Content was checked at the surface at first (0 nm). Then CHF₃ etch was carried out, and silicon content evaluation continues. Obtained result was shown in FIG. 1. Result shows a silicon rich interface with reducing silicon content through the depth of the film.

### Preparation Example 8 of Working Composition 8

Siloxane polymer 7 and D-1 (100: 20.63 by mass) were dissolved in PGMEA to make 15 mass % concentration solution. The solution was then heated to 50° C. for 1 hour. It was confirmed visually that solutes were dissolved. Once the formulation has cooled it was filtered through a 0.2 μm polypropylene filter to obtain working composition 8.

Solvent Resistance Evaluation

Working composition 8 was spin coated onto glass substrate at 500 rpm/10 s then 1,000 rpm for 30 s. Then, the substrate was dried on a hotplate at 100° C. for 2 mins. The substrate was then heated on a hot plate at 350° C. for 5 mins. The thickness of the obtained coating was measured via profilometer. The substrate was then covered with PGMEA for 2 mins. The volume was such that the surface tension of the PGMEA keeps the solvent on the substrate and does not spread over the edges. The substrate was then spun at 1,500 rpm for 10 sec and heated to 100° C. for 2 mins to remove any residual solvent. The thickness was measured again via profilometry. The film retention was 98%.

Thermogravimetric Analysis

The substrate was weighed. Working composition 8 was spin coated onto glass substrate at 500 rpm/10 s then 1,000 rpm for 30s and baked at 70° C. for 2 min to dry the film. Then the substrate with the coating was weighed. The substrate was heated staring from 30° C. to reach 150° C. at 40° C. increase per min. It was then held at 150° C. for 10 mins. It was then heated from 150 to 250° C. at 40° C. increase per min and held at 250° C. for 2 mins. It was then heated from 250 to 350° C. at 40° C. increase per min and held at 350° C. for 2 mins. The mass loss % was negatively correlated with the Mw of the siloxane. The film retention was 96 mass % after these conditions.

1.-16. (canceled)

17. A method of manufacturing segregated layers above a substrate, comprising:
(1) applying a composition above said substrate, wherein said composition comprises solvent (A), siloxane polymer (B) and high-carbon material (C); and
(2) heating said substrate to form segregated layers of antireflective coating made from siloxane polymer (B) and spin-on-carbon coating made from high-carbon material (C), where placed said antireflective coating, spin-on-carbon coating and substrate in this order.

18. The method according to claim 17, wherein said antireflective coating has 50-500 nm thickness and said spin-on-carbon coating has 100-10,000 nm thickness.

19. The method according to claim 17, wherein the composition segregates to said antireflective coating and spin-on-carbon coating, and the self-segregation is caused by phase separation by surface energy difference and/or solubility difference of siloxane polymer (B) and high-carbon material (C).

20. The method according to claim 17, wherein said siloxane polymer (B) comprise at least one unit selected from the group consisting of unit B1, unit B2 and unit B3;
unit B1, unit B2 and unit B3 is each represented by formula B1, formula B2 and formula B3, 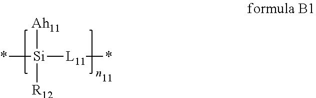
Ah₁₁ is C₁₋₅ aliphatic hydrocarbon,
R₁₂ is -Ah₁₂, —O-Ah₁₂, —O—*, —Si(H)ₚ₁₂(Ah₁₂)_{q12}, —O—Si(H)ₚ₁₂(Ah₁₂)_{q12}, or a single bond to other unit,
Ah₁₂ is C₁-5 aliphatic hydrocarbon,
p12=0, 1, 2 or 3, q12=0, 1, 2 or 3, p12+q12=3,
L₁₁ is single bond or —O—, and n₁₁ is repeating number of unit B1; 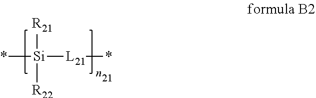
R₂₁ is -Ah₂₁, —O-Ah₂₁, —O—*, —Si(H)ₚ₂₁(Ah₂₁)_{q21}, —O—Si(H)ₚ₂₁(Ah₂₁)_{q21}, or a single bond to other unit,
R₂₂ is -Ah₂₂, —O-Ah₂₂, —O—*, —Si(H)ₚ₂₂(Ah₂₂)_{q22}, —O—Si(H)ₚ₂₂(Ah₂₂)_{q22}, or a single bond to other unit,
Ah₂₁ and Ah₂₂ are each independently C1-5 aliphatic hydrocarbon,
p21, p22, q21 and q22 are each independently 0, 1, 2 or 3, p21+q21=p22+q22=3,
L₂₁ is single bond or —O—, and n₂₁ is repeating number of unit B2; 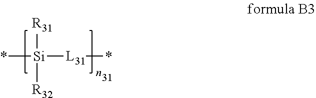
R₃₁ is -Ah₃₁, —O-Ah₃₁, —O—*, —Si(H)ₚ₃₁(Ah₃₁)_{q31}, —O—Si(H)ₚ₃₁(Ah₃₁)_{q31}, or a single bond to other unit,
Ah₃₁ is C₁₋₅ aliphatic hydrocarbon,
p31=0, 1, 2 or 3, q31=0, 1, 2 or 3, p31+q31=3,
R₃₂ is a group consisting of at least 2 group and/or linker selected from the group consisting of phenyl, phenylene, —O—, —(C═O)—, —COO—, —COOH, —NH—, C₁₋₅ aliphatic hydrocarbon group and C₁₋₅ aliphatic hydrocarbon linker,
L₃₁ is single bond or —O—, and n₃₁ is repeating number of unit B3;
0%≤n₁₁/(n₁₁+n₂₁+n₃₁)≤80%, 0%≤n₂₁/(n₁₁+n₂₁+n₃₁)≤80%, and 0%≤n₃₁/(n₁₁+n₂₁+n₃₁)≤80%.
The method according to claim 17, wherein the weight average molecular weight (Mw) of the siloxane polymer (B) is 1,000-100,000.

21. The method according to claim 17, wherein the weight average molecular weight (Mw) of the siloxane polymer (B) is 1,000-100,000.

22. The method according to claim 17, wherein number of atoms contained in said spin-on-carbon coating satisfy below formula C1;
1.5≤{total number of atoms/(number of C−number of O)}≤3.5 formula C1;
where, number of C is the number of carbon atoms in the total number of atoms, and the number of O is the number of oxygen atoms in the total number of atoms.

23. The method according to claim 17, wherein said high-carbon material (C) comprise at least one selected from the group consisting of unit C2, molecule C3 and unit C4 each represented by formula C2, C3 and C4; 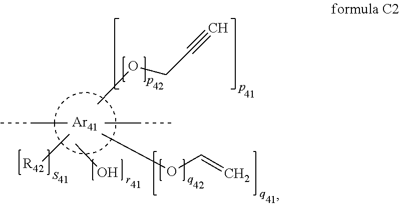
where Ar₄₁ is C₆₋₆₀ hydrocarbon unsubstituted or substituted by R₄₁,
R₄₁ is linear, branch or cyclic C₁₋₂₀ alkyl, amino or alkylamino,
R₄₂ is I, Br or CN,
p₄₁ is number of 0-5, p₄₂ is number of 0-1, q₄₁ is number of 0-5, q₄₂ is number of 0-1, r₄₁ is number of 0-5, s₄₁ is number of 0-5; and
the molecular weight of the high-carbon material (C) comprising unit C2 is 500-4,000; 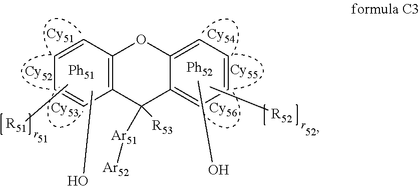
Ar₅₁ is a single bond, C₁₋₆ alkyl, C₆₋₁₂ cycloalkyl, or C₆₋₁₄ aryl,
Ar₅₂ is C₁₋₆ alkyl, C₆₋₁₂ cycloalkyl, or C₆₋₁₄ aryl,
R₅₁ and R₅₂ are each independently C₁₋₆ alkyl, hydroxy, halogen, or cyano,
R₅₃ is hydrogen, C₁₋₆ alkyl, or C₆₋₁₄ aryl,
in the case that Ar₅₂ is C₁₋₆ alkyl or C₆₋₁₄ aryl and R₅₃ is C₁₋₆ alkyl or C₆₋₁₄ aryl, Ar₅₂ and R₅₃ may bond each other to form a hydrocarbon ring,
r₅₁ and r₅₂ are each independently integer of 0-5,
optionally and each independently Cy₅₁, Cy₅₂ and Cy₅₃ rings surrounded by broken lines can be aromatic hydrocarbon ring fused with the adjacent aromatic hydrocarbon ring Ph₅₁,
optionally and each independently Cy₅₄, Cy₅₅ and Cy₅₆ rings surrounded by broken lines can be aromatic hydrocarbon ring fused with the adjacent aromatic hydrocarbon ring Ph₅₂; 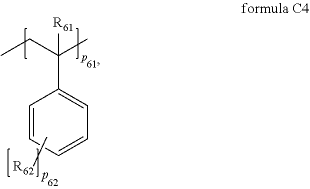
R₆₁ is hydrogen, C₁₋₆ alkyl, halogen, or cyano,
R₆₂ is C₁₋₆ alkyl, halogen, or cyan,
p₆₁ is repeating number, p₆₂ is integer of 0-5.

24. The method according to claim 17, wherein said composition further comprise a thermal acid generator (D) and/or a cross linker (E);
and said composition further comprises additive (F).

25. The method according to claim 24, wherein said additive (F) comprises a surfactant, a thermal base generator, acid, base, a photopolymerization initiator, an agent for enhancing the adhesion to substrates, or any mixture of any of these.

26. The method according to claim 17, wherein said solvent (A) comprises organic solvent; preferably said organic solvent comprises hydrocarbon solvent, ether solvent, ester solvent, alcohol solvent, ketone solvent, or any mixture of any of these.

27. The method according to claim 17, wherein the mass ratio of said solvent (A) based on the total mass of said composition is 60-99 mass %.

28. The method according to claim 17, wherein the mass ratio of said solvent (A) based on the total mass of said composition is 60-99 mass %;
the mass ratio of said siloxane polymer (B) based on the total mass of said composition is 0.1-10 mass %;
the mass ratio of said high-carbon material (C) based on the total mass of said composition is 0.5-30 mass %;
the mass ratio of said thermal acid generator (D) based on the total mass of said siloxane polymer (B) is 10-50 mass %;
the mass ratio of said cross linker (E) based on the total mass of said high-carbon material (C) is 3-50 mass %.

29. The method according to claim 17, wherein said (2) heating is carried out 20-450° C. for 0.1-30 min; and the heating is carried out in an air atmosphere, inert gas, or combination of them.

30. The method according to claim 17, wherein said composition essentially consists of segregating composition.

31. A method of manufacturing a photoresist layer, comprising:
(3) applying a photoresist composition above the segregated layers manufactured by claim 17; and
(4) heating said substrate to form photoresist layer.

32. A method of manufacturing photoresist patterns, comprising:
(5) exposing the photoresist layer manufactured by the method of claim 31; and
(6) developing said exposed layer to form photoresist pattern.

33. A method of manufacturing a processed substrate, comprising:
(7) etching through the resist pattern as a mask, manufactured by claim 32; and
(8) processing the substrate.

34. A method of manufacturing a device, comprising the substrate manufactured by claim 33.

35. The method of manufacturing a device according to claim 34, further comprising forming wiring in the processed substrate.

36. A composition self-segregating to antireflective coating and spin-on-carbon coating, comprising solvent (A), siloxane polymer (B) and high-carbon material (C).
